(19) United States
(12) Patent Application Publication
(10) Pub. No.: US 2005/0255632 A1
(43) Pub. Date: Nov. 17, 2005

(54) Method of fabricating stacked semiconductor device

(75) Inventors: Jin-Chyung Biar, Taipei County (TW); Wu-Chiang Yao, Taipei County (TW); Chi-Pang Huang, Taoyuan County (TW)

Correspondence Address: BACON & THOMAS, PLLC, 625 SLATERS LANE, FOURTH FLOOR, ALEXANDRIA, VA, 22314, US

(73) Assignee: STACK DEVICES Corp., Miaoli County (TW)

(21) Appl. No.: 10/844,507

(22) Filed: May 13, 2004

(51) Int. Cl. H01L 21/44

(52) U.S. Cl. 438/106

(57) ABSTRACT

A method for fabricating a stacked semiconductor device has the steps of: a) Attach a temporary base on a side of a substrate having a conductor pattern and a cavity. b) Provide a first die in the cavity of the substrate and attach it on the temporary base and electrically connect it to the conductor pattern via wires. c) Stack a second die on the first die and electrically connect it to the conductor pattern via wires. d) Provide an insulating layer on the substrate and in the cavity to embed the first die and the second die, and e) remove the temporary base.

### BACKGROUND OF THE INVENTION

1. Field of the Invention

The present invention relates generally to a semiconductor device, and more particularly to a method for fabricating a stacked semiconductor device, which has a thinner die-to-die space for no wire issue.

2. Description of the Related Art

A conventional stacked semiconductor device has a substrate on which a plurality of dies are stacked and electrically connected to a conductor pattern on the substrate via gold wires. Adhesive layers are provided on the substrate and between the stacked dies to bond the dies.

The stacked dies shorten the total width thereof but increase the height thereof. The wires connecting the upper die to the conductor pattern are longer that the electrical signals transmitting via the longer wires are poorer than the shorter wires.

### SUMMARY OF THE INVENTION

The primary objective of the present invention is to provide a stacked semiconductor device, which has a die stack and the height of the stack is shorter than the conventional one.

According to the objective of the present invention, a method for fabricating a stacked semiconductor device comprises the steps of:
a) Attach a temporary base on a side of a substrate having a conductor pattern and a cavity.
b) Provide a first die in the cavity of the substrate and attach it on the temporary base.
c) Stack a second die on the first die.
d) Provide an insulating layer on the substrate and in the cavity to embed the first die and the second die, and
e) Remove the temporary base.

### BRIEF DESCRIPTION OF THE DRAWINGS

FIG. 1 to FIG. 7 are sectional views of a first preferred embodiment of the present invention, showing how the dies stacked on the substrate;

FIG. 8 is a sectional view of a second preferred embodiment of the present invention;

FIG. 9 is a sectional view of a third preferred embodiment of the present invention, and

FIG. 10 is a top view of the third preferred embodiment of the present invention.

### DETAILED DESCRIPTION OF THE INVENTION

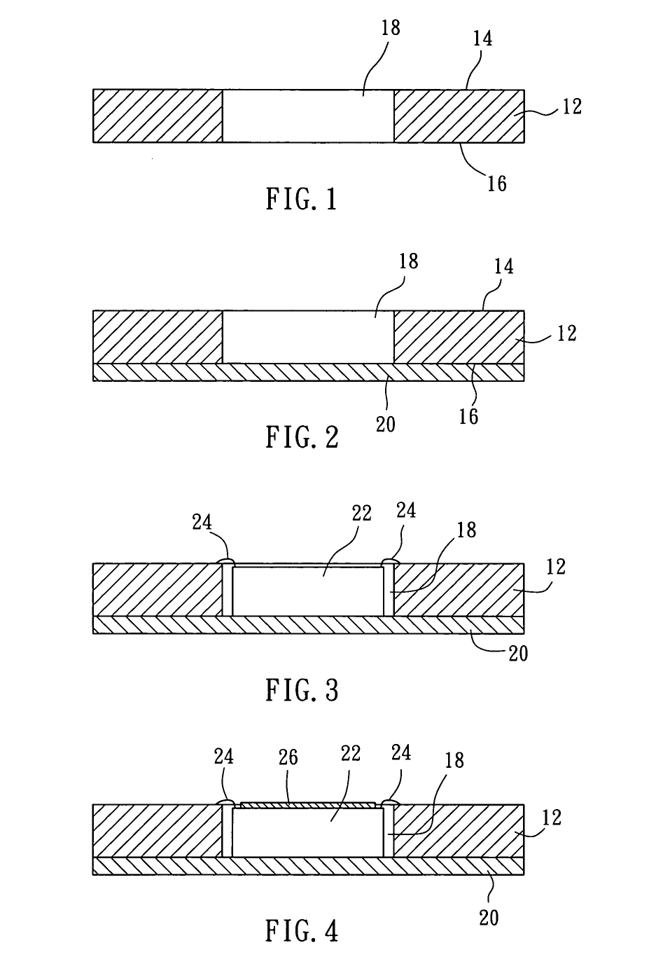

FIG. 1 to FIG. 7 are shown as a method of fabricating a stacked semiconductor device 10 of the first preferred embodiment of the present invention.

As shown in FIG. 1, provide a substrate 12 with a conductor pattern (not shown) and a cavity 18. The substrate 12 has a first side 14 and a second side 16 and the cavity 18 is open at both of the first side 14 and the second side 16.

As shown in FIG. 2, laminate a peelable temporary base 20 on the second side 16 of the substrate 12 to seal an end of the cavity 18. The temporary base 20 is a polyimide tape (PI tape) or a polyethylene terephthalate tape (PET tape) or a polyester film in the present preferred embodiment.

As shown in FIG. 3, provide a first die 22 in the cavity 18 of the substrate 12 and bond it on the temporary base 20. And then, electrically connect connected the first die 22 and the conductor pattern of the substrate 12 by a plurality of gold wires 24.

And then, as shown in FIG. 4, provide an adhesive layer 26 on a top of the first die 22. The adhesive layer 26 is made of epoxy compound, silicon polymer or other suitable die attached materials.

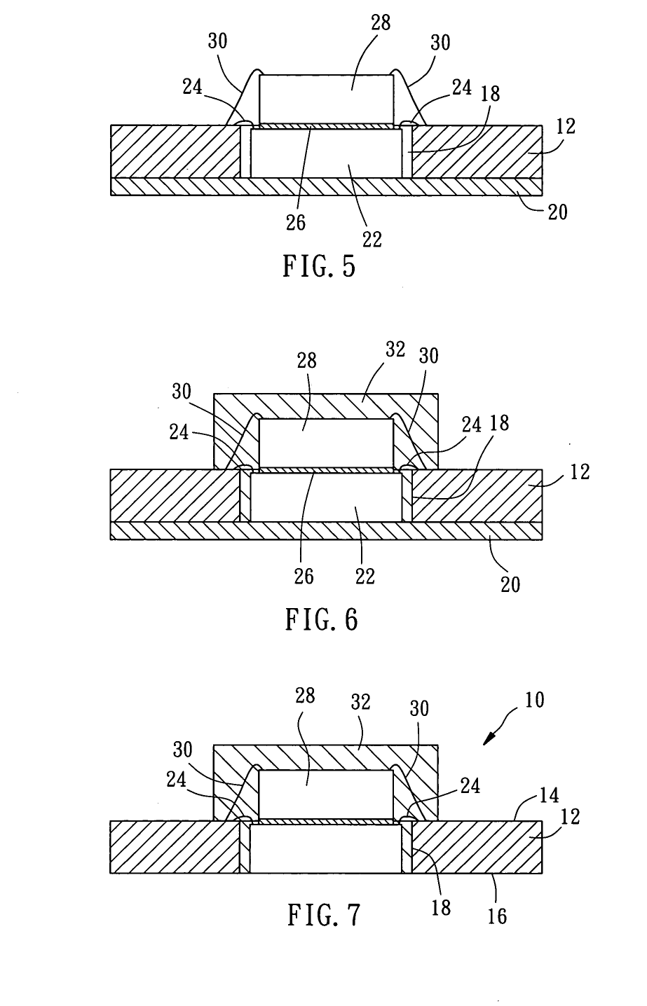

Attach a second die 28 on the adhesive layer 26 and electrically connect the second die 28 and the conductor pattern of the substrate 12 by gold wires 30, as shown in FIG. 5.

The step of wire bonding between the first die 22 and the conductor pattern can shift to here. In other words, the wire bonding steps of the first die 22 and the second die 30 are taken in a single step after the dies have been stacked.

As shown in FIG. 6, provide an insulating layer 32 on the substrate 12 and in the cavity 18 to embed the first die 22, the second die 30 and the wires 24 and 32. The insulating layer 32 is made of epoxy compound, silicon polymer or other suitable materials. The insulating layer 32 and the adhesive layer 26 are preferred made of the same material.

At least, remove the temporary base 20 from the substrate 10 to complete the stacked semiconductor device 10 of the first preferred embodiment of the present invention as shown in FIG. 7.

The first die 22 is embedded in the cavity 18 of the substrate 12 that makes the stacked semiconductor device 10 of the present invention shorter in height. The wires 30 electrically connecting the second die 28 and the conductor pattern are shorter because the second die 28 (the upper die) is proximal to the substrate 12. The electrical signals transmitting via the wires 30 is better.

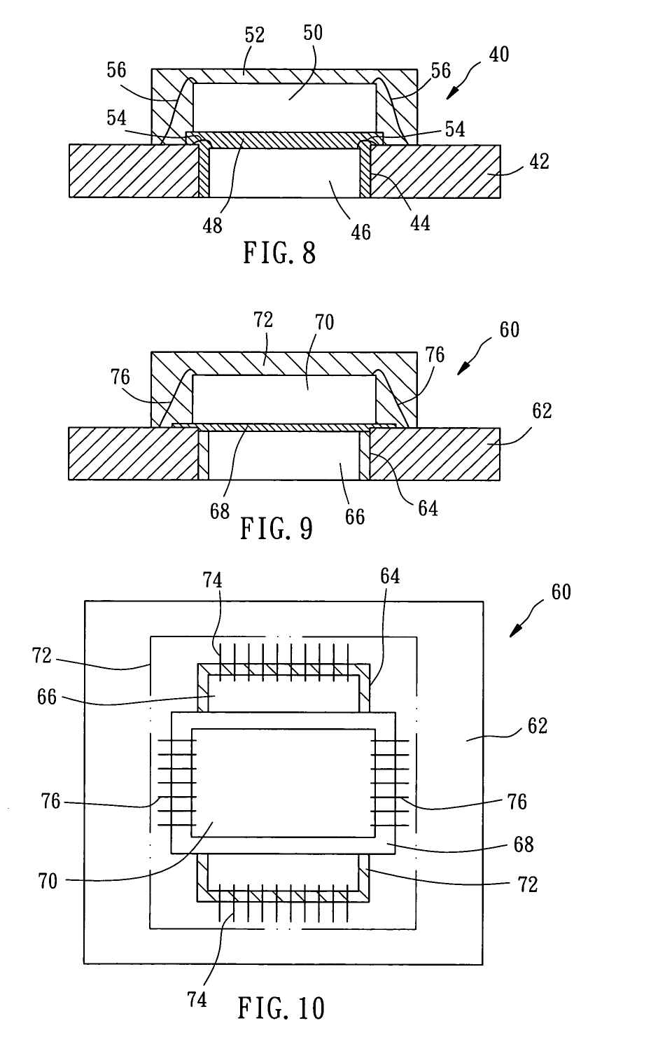

As shown in FIG. 8, a stacked semiconductor device 40 of the second preferred embodiment of the present invention has a substrate 42 with a cavity 44, a first die 46 received in the cavity 44 of the substrate 42, an adhesive layer 48, a second die 50 and an insulating layer 52. In the step of providing the adhesive layer 48, the adhesive layer 48 is provided on a top of the first die 46 and in the cavity 44 of the substrate 42. The adhesive layer 48 further is provided on the substrate 42 to cover gold wires 54, which connect the first die 46 and a conductor pattern (not shown) on the substrate 42. The insulating layer 52 is provided to cover the second die 50 and gold wires 56, which connect the second die 50 and the conductor pattern.

As shown in FIG. 9 and FIG. 10, a stacked semiconductor device 60 of the third preferred embodiment of the present invention, which is similar to the device 10 of the first preferred embodiment, has a substrate 62 with a cavity 64, a first die 66, an adhesive layer 68, a second die 70 and an insulating layer 72. The adhesive layer 68 is provided on both of a top of the first die 66 and on the substrate 62. The second die 70 is attached to the adhesive layer 68, so that the second die 70 is mainly supported by the substrate 62 rather than by the first die 66. The stack's structure is stronger and it still keeps the character of thinner die-to die thickness. As shown in FIG. 10, the first die 66 and the second die 70 are cross to let gold wires 74 and 76 connecting the first die 66 and the second die 70 to the conductor pattern (not shown) on the substrate 62 are not overlapped. The size of the second die 70 is not restricted by the first die 66 in this condition.

The stacked semiconductor devices of the present invention can be applied to the ball grid array (BGA) substrates or the land grid array (LGA) substrates.

1. A method for fabricating a stacked semiconductor device, comprising the steps of:
a) attaching a temporary base on a side of a substrate having a conductor pattern and a cavity;
b) providing a first die in the cavity of the substrate and attaching it on the temporary base;
c) stacking a second die on the first die;
d) providing an insulating layer on the substrate and in the cavity to embed the first die and the second die, and
e) removing the temporary base.

2. The method as defined in claim 1, further comprising the steps of electrically connecting the fist die to the conductor pattern of the substrate via wires in the step b and electrically connecting the second die to the conductor pattern of the substrate via wires in the step c.

3. The method as defined in claim 1, further comprising the step of electrically connecting the fist die and the second die to the conductor pattern of the substrate via wires after the step c.

4. The method as defined in claim 1, further comprising the step of providing an adhesive layer on the first die before the step c, wherein the second die is attached on the adhesive layer.

5. The method as defined in claim 1, further comprising the steps of electrically connecting the fist die to the conductor pattern of the substrate via wires, and then providing an adhesive layer on the first die and on the substrate to embed at least portions of the wires before the step c.

6. The method as defined in claim 1, wherein the second die has at least a portion attached on the substrate.

7. The method as defined in claim 1, wherein the temporary base is chosen from a polymide tape (PI tape) or a polyethylene terephthalate tape (PET tape) or a polyester film.

8. A method for fabricating a stacked semiconductor device, comprising the steps of:
a) attaching a temporary base on a side of a substrate having a conductor pattern and a cavity;
b) providing a first die in the cavity of the substrate and attaching it on the temporary base;
c) providing an adhesive layer in the cavity of the substrate;
d) stacking a second die on the second die, and
e) removing the temporary base.

9. The method as defined in claim 8, further comprising the steps of electrically connecting the fist die to the conductor pattern of the substrate via wires in the step b and electrically connecting the second die to the conductor pattern of the substrate via wires in the step d.

10. The method as defined in claim 8, further comprising the step of electrically connecting the fist die and the second die to the conductor pattern of the substrate via wires after the step d.

11. The method as defined in claim 8, further comprising the step of providing an insulating layer on the substrate to embed the first die after the step d.

12. The method as defined in claim 9, wherein the adhesive layer has a portion coated on the substrate to embed at least portions of the wires.

13. The method as defined in claim 8, wherein the adhesive layer further is coated both on first die and the substrate to attach at least a portion of the second die on the substrate.

14. The method as defined in claim 8, wherein the temporary base is chosen from a polymide tape (PI tape) or a polyethylene terephthalate tape (PET tape) or a polyester film.
